(19) United States
(12) Patent Application Publication
(10) Pub. No.: US 2021/0138763 A1
(43) Pub. Date: May 13, 2021

(54) BONDED STRUCTURE AND METHOD FOR PRODUCING SAME, AND HEAT EXCHANGER

(71) Applicant: DENSO CORPORATION, Kariya-city (JP)

(72) Inventors: Masami SAITO, Kariya-city (JP); Koji KONDO, Kariya-city (JP); Masashi TOTOKAWA, Kariya-city (JP); Hirotaka MIYANO, Kariya-city (JP); Yoshitake SUGANUMA, Nagakute-shi (JP); Kenichi YAGI, Nagakute-shi (JP); Yuichi KATO, Nagakute-shi (JP); Kunio MORI, Morioka-shi (JP); Katsuhito MORI, Morioka-shi (JP); Taiga HANDA, Morioka-shi (JP)

(21) Appl. No.: 17/150,057

(22) Filed: Jan. 15, 2021

Related U.S. Application Data
(63) Continuation of application No. PCT/JP2019/023239, filed on Jun. 12, 2019.

(30) Foreign Application Priority Data
Jul. 17, 2018 (JP) 2018-134019

(51) Int. Cl. B32B 7/12; F28F 1/32; F28F 21/08; H01L 23/36; H05K 7/20; B32B 37/14; B32B 15/08

(52) U.S. Cl. CPC B32B 7/12; F28F 1/32; F28F 21/08; B32B 2307/302; H05K 7/2039; B32B 37/14; B32B 15/08; H01L 23/36

(57) ABSTRACT

A bonded structure has a first bonded member with a first bonding surface, a second bonded member with a second bonding surface, and a bonding resin layer containing a polymer, disposed between the first bonding surface and the second bonding surface. The polymer in the bonding resin layer has polymer main chains oriented in an intersecting direction that intersects with the first bonding surface and the second bonding surface. The intersecting direction preferably extends along the thickness direction of the bonding resin layer. A heat exchanger has the bonded structure, and the first bonded member serves as a tubular member, and the second bonded member serves as a heat dissipation fin.

### CROSS-REFERENCE TO RELATED APPLICATION

The present application is a continuation application of International Application No. PCT/JP2019/023239 filed on Jun. 12, 2019, which is based on and claims the benefit of priority from Japanese Patent Application No. 2018-134019 filed on Jul. 17, 2018. The contents of these applications are incorporated herein by reference in their entirety.

### BACKGROUND

The present disclosure relates to a bonded structure and a method for producing the same, and a heat exchanger.

Conventionally, for example, in a heat exchanger that has a tubular member and a heat dissipation fin, metal bonding having low thermal resistance, such as brazing, is used for bonding the tubular member and the heat dissipation fin.

Further, preceding JP 2017-216452 A discloses herein a technique of orienting carbon nanotubes to form a bonded structure with high thermal conductivity.

### SUMMARY

An aspect of the present disclosure is a bonded structure including: a first bonded member having a first bonding surface; a second bonded member having a second bonding surface; and a bonding resin layer containing a polymer, in which the polymer has polymer main chains oriented in an intersecting direction that intersects with the first bonding surface and the second bonding surface.

It is to be noted that the reference signs in the parenthesis, mentioned in the claims, are intended to the correspondence relations with the specific means described in the embodiments described later, but not intended to limit the technical scope of the present disclosure.

### BRIEF DESCRIPTION OF THE DRAWINGS

The above-mentioned object of the present disclosure, and other objects, features, and advantages will become more apparent from the following description with reference to the accompanying drawings below.

FIG. 1 is an explanatory diagram schematically illustrating a bonded structure according to Embodiment 1.

FIGS. 2A to 2C are explanatory diagrams schematically illustrating typical forms and combination examples for a first bonding surface of a first bonded member and a second bonding surface of a second bonded member in the bonded structure according to Embodiment 1.

FIG. 3 is an explanatory diagram schematically illustrating a part of a heat exchanger according to Embodiment 1, including the bonded structure according to Embodiment 1.

FIG. 4 is an explanatory diagram illustrating enlargements of a tubular member, a heat dissipation fin, and a bonding resin layer in the heat exchanger according to Embodiment 1.

FIG. 5 is an explanatory diagram illustrating a further enlargement of the enlarged view in FIG. 4 in detail.

FIG. 6 is an explanatory diagram schematically illustrating a microstructure in the bonded structure according to Embodiment 1.

FIG. 7 is an explanatory diagram for describing a method for producing a bonded structure according to Embodiment 2.

FIGS. 8A to 8C are explanatory diagrams for describing a method for preparing a sample according to Experimental Example 1.

FIG. 9 is a diagram showing the relation (Raman spectrum) between wavelength and Raman intensity, obtained in Experimental Example 1.

FIG. 10 is a graph showing the relations between the molecular structure of a polymer and the shrinkage ratio of the polymer, and the thermal conductivity of a bonding resin layer, obtained in Experimental Example 2.

FIG. 11 is an explanatory diagram for describing a method for preparing a sample according to Experimental Example 3.

FIG. 12 is an explanatory diagram for describing a method for measuring the heat flow and thermal conductivity of a bonding resin layer in Experimental Example 3.

FIG. 13 is a graph showing the relation between time and the volume change rate of a polymer material, obtained in Experimental Example 4.

### DETAILED DESCRIPTION OF THE PREFERRED EMBODIMENTS

The inventor of the present disclosure has studied a bonded structure that is capable of reducing thermal resistance even in the case of bonding with a resin used, and a heat exchanger with the structure used.

The above described prior art has the following problems. For metal bonding by brazing or the like, typically, at high temperatures of 500° C. or higher, surface activity is imparted with a flux, and the bonding metal is melted. For that reason, in the case where the member to be bonded is a resin member, metal bonding is difficult to employ. Moreover, bonding with a resin used is, because the bonded part has high thermal resistance, difficult to be used for heat exchangers.

Further, the above-described bonding technique of orienting carbon nanotubes is difficult to employ for a member to be bonded in a complex shape, such as a heat dissipation fin.

An object of the present disclosure is to provide a bonded structure that is capable of reducing thermal resistance even in the case of bonding with a resin, and a heat exchanger using the structure.

An aspect of the present disclosure is a bonded structure including: a first bonded member having a first bonding surface; a second bonded member having a second bonding surface; and a bonding resin layer containing a polymer, disposed between the first bonding surface and the second bonding surface,

in which the polymer has polymer main chains oriented in an intersecting direction that intersects with the first bonding surface and the second bonding surface.

Another aspect of the present disclosure is a method for producing the bonded structure mentioned above, which includes:

disposing a polymer material containing the polymer between the first bonding surface of the first member to be bonded and the second bonding surface of the second member to be bonded; and

heating the polymer material disposed, and then cooling the polymer material,

in which between disposing and cooling the polymer material, polymer chains of the polymer are linked by covalent bonds to the first bonding surface and the second bonding surface, and the polymer is then shrunk to orient the polymer main chains in the intersecting direction that intersects with the first bonding surface and the second bonding surface.

Yet another aspect of the present disclosure is a heat exchanger including the bonded structure mentioned above,

in which the first bonded member serves as a tubular member, and the second bonded member serves as a heat dissipation fin.

In the bonded structure, the polymer main chains constituting the polymer included in the bonding resin layer are oriented in the intersecting direction that intersects with the first bonding surface of the first bonded member and the second bonding surface of the second bonded member. Thus, the bonding resin layer is more likely to produce phonon vibration of the polymer main chain as compared with a case where the polymer main chain is random, thereby improving the thermal conductivity. Accordingly, the bonded structure is capable of reducing the thermal resistance in the bonding resin layer, although the bonding with the resin is used.

The method for producing the bonded structure is configured as mentioned above. Thus, the method for producing the bonded structure makes it possible to produce the bonded structure capable of reducing the thermal resistance in the bonding resin layer at lower temperatures and without any flux, as compared with a case of using metal bonding by brazing.

The heat exchanger is configured as mentioned above. In the heat exchanger, the bonding resin layer disposed between the tubular member and the heat dissipation fin has favorable thermal conductivity. Thus, the heat exchanger is advantageous for the improvement of heat dissipation characteristics.

### Embodiment 1

A bonded structure according to Embodiment 1 will be described with reference to FIGS. 1 to 6. As shown in FIG. 1, the bonded structure 1 according to the present embodiment has a first bonded member 11 having a first bonding surface 110, a second bonded member 12 having a second bonding surface 120, and a bonding resin layer 13.

Examples of the materials for the first bonded member 11 and the second bonded member 12 can include metal materials (the metals herein include alloys, the same applies hereinafter), resin materials, and ceramic materials. The material of the first bonded member 11 and the material of the second bonded member 12 may be the same material, or may be different materials from each other. Examples of the combination of the first bonded member 11 and the second bonded member 12 can include a combination of a metal material and the same metal material or a different metal material, a combination of a metal material and a resin material, a combination of a resin material and a metal material, and a combination of a resin material and the same resin material or a different resin material.

Examples of the metal materials can include aluminum, aluminum alloys, iron, iron-based alloys, copper, copper alloys, nickel, nickel alloys, zinc, zinc alloys, tin, tin alloys, titanium, titanium alloys, tungsten, tungsten alloys, and silicon. Examples of the resin materials can include polyamide resins such as a nylon resin, polyolefin resins, cellulose resins, and polyvinyl resins. Examples of the ceramic materials can include alumina, tungsten carbides, zirconia, silicon nitrides, silicon carbides, titanium oxides, and various types of glass.

The first bonding surface 110 and the second bonding surface 120 may be both formed to have flat surfaces as illustrated in FIG. 2A, or may be both formed to have curved surfaces as illustrated in FIG. 2B, or as illustrated in FIG. 2C, either one of the surfaces may be formed to have a flat surface, whereas the other thereof may be formed to have a curved surface.

The first bonding surface 110 can specifically serve as a part of the surface of the first bonded member 11. Similarly, the second bonding surface 120 can specifically serve as a part of the surface of the second bonded member 12. The bonding resin layer 13 is disposed between the first bonding surface 110 and the second bonding surface 120, and bonded to the first bonding surface 110 and the second bonding surface 120. As illustrated in, for example, FIGS. 5 and 6, in the first bonded member 11, at least the first bonding surface 110 can be subjected to a surface treatment, for example, provided with a catalyst layer 111, from viewpoints such as improvement in the property of bonding to the bonding resin layer 13. Similarly, in the second bonded member 12, at least the second bonding surface 120 can be subjected to a surface treatment, for example, provided with a catalyst layer 121, from viewpoints such as improvement in the property of bonding to the bonding resin layer 13. It is to be noted that in the case where, for example, surface treatment layers such as catalyst layers are formed on the first bonding surface 110 and the second bonding surface 120, the above-described surfaces of the first bonding surface 110 and second bonding surface are regarded as the surfaces of the surface treatment layers. In the case where the first bonding surface 110 of the first bonded member 11 and the second bonding surface 120 of the second bonded member 12 are made of metal materials, specifically, the catalyst layers 111 and 121 can be composed of, for example, glass such as an aluminosilicate, a silicate, or a borosilicate, or surface-modifying molecules such as N,N′-bis(2-amionethyl)-6-(3-triethoxysilylpropyl)amino-1,3,5-triazine-2,4-diamine or SAMs (self-assembled monolayers).

Further, the present embodiment provides, as illustrated in, for example, FIGS. 3 to 5, an example of employing the bonded structure 1 for a heat exchanger 2 (a heater core or the like) that has a tubular member 21 and a heat dissipation fin 22 bonded to the tubular member 21. More specifically, according to the present embodiment, the first bonded member 11 serves as the tubular member 21, and the first bonding surface 110 serves as a part of the tubular member 21. In addition, the second bonded member 12 serves as the heat dissipation fin 22, and the second bonding surface 120 serves as a part of the heat dissipation fin 22. In this case, the first bonded member 11 and the second bonded member 12 can be both composed of aluminum or an aluminum alloy. Furthermore, the first bonded member 11 and the second bonded member 12 may have, on the first bonding surface 110 and the second bonding surface 120, the catalyst layers 111 and 121 composed of an aluminosilicate through a reaction of dissolving and replacing Al or the like as illustrated in FIG. 6.

The bonding resin layer 13 includes a polymer 130. In the bonding resin layer 13, the polymer 130 has, as illustrated in FIG. 6, polymer main chains 130A oriented in an intersecting direction X that intersects with the first bonding surface 110 and the second bonding surface 120. The polymer main chain 130A refers to a main chain that forms the skeleton of the polymer 130. The polymer main chain 130A may have a functional group, a low-molecular-weight molecule, or the like bonded thereto. It is to be noted that it is difficult to produce a situation fully orienting all of the polymer main chains 130A of the polymer 130 in the intersecting direction X. Accordingly, the polymer 130 of the bonding resin layer 13 may include polymer main chains 130A that are not oriented in the intersecting direction X, as long as the effect of reducing the thermal resistance is achieved.

In the present embodiment, the intersecting direction X can extend along the thickness direction T of the bonding resin layer 13. This configuration makes it easier for heat to flow between the first bonding surface 110 and the second bonding surface 120, thus making the thermal conductivity of the bonding resin layer 13 more likely to be improved. It is to be noted that the thickness direction T of the bonding resin layer 13 can be also regarded as a direction that extends along the line segment corresponding to the shortest distance between the first bonding surface 110 and the second bonding surface 120. Thus, in the case where the first bonding surface 110 and the second bonding surface 120 have the shapes of FIG. 2A described above, the direction of an arrow A is regarded as the direction extending along the thickness direction T of the bonding resin layer 13. Similarly, in the case where the first bonding surface 110 and the second bonding surface 120 have the shapes of FIG. 2B described above, the direction of an arrow B is regarded as the direction extending along the thickness direction T of the bonding resin layer 13. In the case where the first bonding surface 110 and the second bonding surface 120 have the shapes of FIG. 2C described above, the direction of the arrow C is regarded as the direction extending along the thickness direction T of the bonding resin layer 13.

The polymer 130 preferably has a first polymer chain 131 linked to the first bonding surface 110 by a covalent bond, and a second polymer chain 132 linked to the second bonding surface 120 by a covalent bond. This configuration strengthens the bonding between the bonding resin layer 13 and the first bonding surface 110 and the bonding between the bonding resin layer 13 and the second bonding surface 120, thus making the bonding strength of the bonded structure 1 more likely to be improved.

It is to be noted that the first polymer chain 131 and the second polymer chain 132 may be directly linked to the first bonding surface 110 and the second bonding surface 120 by covalent bonds, or may be linked to catalyst layers or the like formed on the first bonding surface 110 and the second bonding surface 120 by covalent bonds. In addition, the polymer 130 is typically composed of multiple polymer chains entangled with each other, and thus may have intermediate polymer main chains 133 that are not linked to the first bonding surface 110 or the second bonding surface 120. Furthermore, the polymer chains include both a main chain and a side chain. Thus, the first polymer chain 131 and the second polymer chain 132 may form the above-mentioned bonds in the main chain or on a side chain.

For the polymer 130, more preferably, a bonded molecule 134 linked to the first polymer chain 131 by a covalent bond is linked to the first bonding surface 110 by a covalent bond, whereas a bonded molecule 134 linked to the second polymer chain 132 by a covalent bond is linked to the second bonding surface 120 by a covalent bond. This configuration makes it easier to select the polymer 130 in which the polymer main chains 130A are more likely to be oriented, while improving the bonding strength of the bonded structure 1, thus enlarging the range of choice for the polymer 130 and making it easier to achieve a target thermal conductivity. In addition, each bonding surface and each polymer chain are bonded by the molecular chain, thus making heat more likely to transfer through the molecular chain, and also providing advantages such as being capable of efficiently transferring heat.

It is to be noted that FIG. 6 specifically shows therein an example in which the bonded molecule 134 linked to the first polymer chain 131 by a covalent bond is linked by a covalent bond to the material constituting the catalyst layer 111 formed on the surface of the first bonding surface 110, whereas the bonded molecule 134 linked to the second polymer chain 132 by a covalent bond is linked by a covalent bond to the material constituting the catalyst layer 121 formed on the surface of the second bonding surface 120. The presence or absence of the covalent bonds described above can be confirmed by electron spectroscopy for chemical analysis (ESCA) or XAFS.

According to the present embodiment, specifically, the polymer 130 is preferably a linear polymer. This configuration makes the polymer main chains 130A more likely to align in the intersecting direction X in which heat easily flows, thus providing the bonded structure 1 that is more likely to reduce the thermal resistance.

Examples of the polymer 130 can include polyolefins such as polyethylene and polypropylene, and polyvinyl chloride. One of these polymers can be used, or two or more thereof can be used in combination. Among these polymers, polyethylene or the like is preferably employed as the polymer 130 from viewpoints such as being a linear polymer and making the polymer chains 130A more likely to be oriented.

Furthermore, examples of the bonded molecule 134 described above can include triazine thiols and triazine thiol derivatives. One of these molecules can be used, or two or more thereof can be used in combination. Further, N, N′-bis(2-aminoethyl)-6-(3-triethoxysilylpropyl) amino-1,3,5-triazine-2,4-diamine, (3-triethoxysilylpropyl) amino-1,3,5-triazine-2,4-diazido, and the like can be used as the bonded polymer 134.

In the bonding resin layer 13, the orientation ratio of the polymer 130, defined by 100×ratio 2/ratio 1, is preferably 3% or more, more preferably 5% or more, further preferably 8% or more. The ratio 1 refers to the absolute value of the ratio (Raman intensity for side chain vibration of polymer 130)/(Raman intensity for main chain vibration of polymer 130), determined for a plane perpendicular to the thickness direction of the bonding resin layer 13 in a non-oriented sample in which the polymer main chains 130A constituting the polymer 130 are not oriented. Furthermore, the ratio 2 refers to the absolute value of the ratio (Raman intensity for side chain vibration of polymer 130)/(Raman intensity for main chain vibration of polymer 130), determined for a plane perpendicular to the thickness direction of the bonding resin layer 13 in an oriented sample in which the polymer main chains 130A constituting the polymer 130 are oriented. This configuration ensures the orientation of the polymer main chains 130A in the intersecting direction X that intersects with the first bonding surface 110 and the second bonding surface 120, thereby making it easier to ensure the reduction in thermal resistance. In addition, the configuration also has advantages such as improved bonding strength. It is to be noted that the conditions for measuring the Raman intensity by Raman spectroscopy desirably resolves the site to be subjected to the measurement, and acquire information on the interior of the bonded resin part as much as possible. In particular, when resolved, in the high-resolution and high-power Raman spectrometer, the measurement is allowed from the depth of 100 μm or more, desirably 200 μm or more with respect to the resolved plane. In this regard, the measurement wavelength can be 1060 cm⁻¹ in the case of measuring the Raman intensity for the skeleton vibration of a C—C bond that forms the main chain skeleton of a polymer used, and 2750 cm⁻¹ in the case of measuring the Raman intensity for the vibration of a C—H bond that forms a side chain of the polymer used. In addition, in Raman spectroscopy, various polymers have reference peaks, and can be similarly determined in accordance with the increase or decrease of the vibration wavelength in the longitudinal direction of the molecular chain or the increase or decrease of the vibration wavelength of the side chain with respect to the peaks. Also in this case, the orientation ratio of the polymer 130 is preferably 3% or more, more preferably 5% or more, further preferably 8% or more. In addition, the orientation ratio of the polymer 130, defined by 100×ratio 2/ratio 1, can be adjusted to 500% or less, because the void amount increases with decrease in internal volume as the orientation proceeds.

In the foregoing, in the case where the plane perpendicular to the thickness direction of the bonding resin layer 13 is used as a measurement surface, the polymer main chains 130A can be considered more oriented in the thickness direction T of the bonding resin layer 13 as the main chain vibration of the polymer 130 has a lower Raman intensity, and as the side chain vibration of the polymer 130 has a higher Raman intensity. For example, in the case where the polymer 130 is a polyethylene, the polymer main chains 130A can be considered more oriented in the thickness direction T of the bonding resin layer 13 as the vibration of a C—C bond that forms the skeletons of the polymer main chains 130A has a lower Raman intensity, and as the vibration of a C—H bond that forms the polymer side chains has a higher Raman intensity. In contrast, the polymer main chains 130A can be considered more oriented in a direction perpendicular to the thickness direction T of the bonding resin layer 13 as the vibration of the C—C bond has a higher Raman intensity, and as the vibration of the C—H bond has a lower Raman intensity.

In the bonded structure 1, the positions of the first bonding surface 110 and second bonding surface 120 are preferably fixed relative to each other. It is to be noted that fixing the positions relative to each other herein means that the positions of the first bonding surface 110 and second bonding surface 120 are fixed so as not to come closer to each other in the stage before the first bonding surface 110 and the second bonding surface 120 are bonded to each other by the bonding resin layer 1. This configuration makes it easier to orient the polymer main chains 130A in the intersecting direction X that intersects with the first bonding surface 110 and the second bonding surface 120, through the shrinkage of the polymer 130 with the polymer main chains 130A covalently bonded to both the first bonding surface 110 and the second bonding surface 120 in the production of the bonded structure 1 (for details, see Embodiment 2).

Examples of the method for positionally fixing the first bonding surface 110 and the second bonding surface 120 relative to each other can include a method of providing a part of either the first bonding surface 110 or the second bonding surface 120 in abutment with the other bonding surface, a method of sandwiching a spacer member 3 between the first bonding surface 110 and the second bonding surface 120 so as not to reduce the distance between the first bonding surface 110 and the second bonding surface 120, and a method of incorporating hard coarse particles in the bonding resin layer 13. According to the present embodiment, a part of the second bonding surface 120 is provided in abutment with the first bonding surface 110, thereby fixing the positions of the first bonding surface 110 and second bonding surface 120 relative to each other so as not to come closer to each other. In addition, in the heat exchanger 2, the heat dissipation fin 22 is bonded at multiple sites at the surface of the tubular member 21, and in this case, the second bonding surface 120 may make partial contact with the first bonding surface 110 at all of the bonded sites, or the second bonding surface 120 may fail to make partial contact with the first bonding surface 110 at some of the sites. The latter configuration is allowed because, even if the second bonding surface 120 fails to make partial contact with the first bonding surface 110 at some of the sites, the first bonding surface 110 and the second bonding surface 120 are, as a whole, positionally fixed relative to each other so as not come closer to each other by the action of the other sites where the second bonding surface 120 makes partial contact with the first bonding surface 110. It is to be noted that the heat exchanger 2 specifically includes a structure where the metallic heat dissipation fin 22 configured in an accordion form has a leading protrusion in abutment with a part of the surface of the metallic tubular member 21. Further, basically, the bonding resin layer 13 is formed in the gaps formed between the vicinity of the leading protrusions of the heat dissipation fin 22 and the surface of the tubular member 21. The heat exchanger 2 may have sites where the leading protrusions of the heat dissipation fin 22 are provided without any abutment on a part of the surface of the tubular member 21. In addition, the heat dissipation fin 22 typically has multiple leading protrusions, and the heat exchanger 2 may have sites where the resin bonding layer 13 is not provided between the leading protrusions and the tubular member 21.

In the bonded structure 1, the thermal conductivity of the bonding resin layer 13 can be specifically 1 W/m·K or more, preferably 2.5 W/m·K or more, more preferably 3.5 W/m·K or more. It is to be noted that the thermal conductivity of the bonding resin layer 13 can be measured in accordance with ASTM E1530. Specifically, with the use of a thermal resistor in accordance with ASTM E1530, the sample shown in FIGS. 8A to 8C described later can be prepared with the use of an aluminum plate of 1 mm in thickness, 22 mm in width, and 22 mm in length, and subjected to the measurement. As long as the thermal conductivity of the bonding resin layer 13 falls within the range mentioned above, the reduction of thermal resistance in the bonding resin layer 13 can be ensured. It is to be noted that the thermal conductivity of the bonding resin layer 13 is preferably higher, but can be 15 W/m·K or less from viewpoints such as void generation with orientation.

In the bonded structure 1 according to the present embodiment, the polymer main chains 130A constituting the polymer 130 included in the bonding resin layer 13 are oriented in the intersecting direction X (the thickness direction T of the bonding resin layer 13 according to the present embodiment) that intersects with the first bonding surface 110 of the first bonded member 11 and the second bonding surface 120 of the second bonded member 12. Thus, the bonding resin layer 13 is more likely to produce phonon vibration of the polymer main chains 130A as compared with a case where the polymer main chains 130A are random, thereby improving the thermal conductivity. Accordingly, the bonded structure 1 according to the present embodiment is capable of reducing thermal resistance in the bonding resin layer 13, in spite of the bonding with the resin used.

### Embodiment 2

A method for producing a bonded structure according to Embodiment 2 will be described with reference to FIG. 7. It is to be noted that among the reference signs used in Embodiment 2 and the subsequent embodiment, the same reference signs as those used in the already described embodiment denote the same constituent elements or the like as those in the already described embodiment, unless otherwise described. In addition, the present embodiment can appropriately refer therein to the description of Embodiment 1, whereas Embodiment 1 described above can appropriately refer therein to the description of the present embodiment.

The method for producing the bonded structure according to the present embodiment is a method for producing the bonded structure 1 including the first bonded member 11 having the first bonding surface 110, the second bonded member 12 having the second bonding surface 120, and the bonding resin layer 13 containing the polymer 130, disposed between the first bonding surface 110 and the second bonding surface 120, in which the polymer 130 has the polymer main chain 130A oriented in the intersecting direction X that intersects with the first bonding surface 110 and the second bonding surface 120, as described above in Embodiment 1.

Specifically, the method for producing the bonded structure according to the present embodiment includes, as illustrated in FIG. 7(a), a step of disposing a polymer material 135 containing the polymer 130 between the first bonding surface 110 of the first member 11 to be bonded and the second bonding surface 120 of the second member 12 to be bonded.

According to the present embodiment, as shown in FIG. 7(a), the positions of the first bonding surface 110 and second bonding surface 120 are fixed relative to each other by disposing the spacer member 3 between the first bonding surface 110 and the second bonding surface 120. More specifically, the relative distance between the first bonding surface 110 and the second bonding surface 120 is kept constant. It is to be noted that the method for positionally fixing the first bonding surface 110 and the second bonding surface 120 relative to each other is not to be considered limited to the foregoing.

The polymer material 135 containing the polymer can specifically contain the polymer 130 and a solvent 136 that is capable of dissolving or dispersing the polymer 130. Examples of the polymer 130 for use in the preparation of the polymer material 135 can include polymer particles. In addition, in the case of using the bonding molecules 134 described in Embodiment 1, polymer particles coated with the bonding molecules 134 or the like can be used. This makes it easier to form a bonded structure where the bonded molecule 134 linked to the first polymer chain 131 by a covalent bond is linked to the first bonding surface 110 by a covalent bond and the bonded molecule 134 linked to the second polymer chain 132 by a covalent bond is linked to the second bonding surface 120 by a covalent bond, as compared with a case where the polymer particles and the bonding molecules 134 are blended separately.

It is to be noted that FIG. 7(a) shows therein an example in which the polymer material 135 containing the polymer particles (polymer 130) coated with the bonding molecules 134 and the solvent 136 is applied in the form of a layer without any space in the gap formed between the first bonding surface 110 and the second bonding surface 120.

The method for producing the bonded structure according to the present embodiment includes a step of heating the polymer material 135 disposed as described above, and then cooling the polymer material 135. The heating temperature for the polymer material 135 can be variously selected in consideration of the type of the polymer 130 used, the boiling point of the solvent 136, and the like. In addition, the cooling mentioned above can be performed by rapid cooling from viewpoints such as the orientation of the polymer main chains 130A.

In this regard, in the method for producing the bonded structure according to the present embodiment, between disposing and cooling the polymer material 135, the polymer chains of the polymer 130 are directly or indirectly linked by covalent bonds to the first bonding surface 110 and the second bonding surface 120 (in the case where the catalyst layers 111 and 112 are formed, the catalyst layer 111 of the first bonding surface 110 and the catalyst layer 121 of the second bonding surface 120), and the polymer 130 is then shrunk, thereby orienting the polymer main chains 130A in the intersecting direction X that intersects with the first bonding surface 110 and the second bonding surface 120.

According to the present embodiment, specifically, after first disposing the polymer material 135 in the form of a layer between the first bonding surface 110 and the second bonding surface 120 of the second member 12 to be bonded, the polymer chains of the polymer 130 are linked to the first bonding surface 110 and the second bonding surface 120 by covalent bonds. In the case where the polymer material 135 contains the bonding molecules 134, the bonding molecules 134 can be covalently bonded to the polymer 130 and the first bonding surface 110 and covalently bonded to the polymer 130 and the second bonding surface 120 while using interaction, interfacial chemical reaction, and the like between the bonding molecules 134. In this regard, the polymer material 135 can be heated in order to promote the formation of the covalent bonds. It is to be noted that the bonding molecules 134 may be covalently bonded to the polymer 130 and the first bonding surface 110 and covalently bonded to the polymer 130 and the second bonding surface 120, for example, during heating the polymer material 135 as described later. Alternatively, in the case of using no bonding molecules 134, during heating the polymer material 135 as described later, the polymer 130 may be covalently bonded to the first bonding surface 110, and the polymer 130 may be covalently bonded to the second bonding surface 120.

Next, the polymer 130 is shrunk. Examples of the method therefor include, for example, in the case where the polymer material 135 used contains the solvent 136, a method of evaporating the solvent 136 by heating and a method of evaporating the solvent 136 and melting the polymer 130 by heating. In addition, examples of the method can include, for example, in the case where the polymer material 135 used contains no solvent 136, a method of melting the polymer 130 by heating, thereby eliminating voids. These methods make it possible to shrink the polymer 130 linked to the first bonding surface 110 and the second bonding surface 120. Further, FIG. 7(b) illustrates therein the evaporation of the solvent 136 and then the reduced volume of the polymer material 135 by heating at a temperature capable of evaporating the solvent 136. Furthermore, FIG. 7(c) illustrates therein the polymer 130 molten and then the polymer 130 shrunk by heating at a temperature capable of melting the polymer 130, which is a higher temperature than in the case of the solvent evaporation.

The shrinkage of the polymer 130 linked to the first bonding surface 110 and the second bonding surface 120, as shown in FIG. 7(d), stretches the polymer 130, thereby making it possible to orient the polymer main chains 130A in the intersecting direction X (the thickness direction T of the bonding resin layer 13 according to the present embodiment) that intersects with the first bonding surface 110 and the second bonding surface 120.

The method for producing the bonded structure according to the present embodiment makes it possible to produce the bonded structure 1 capable of reducing the thermal resistance in the bonding resin layer 13 at lower temperatures and without any flux, as compared with a case of using metal bonding by brazing.

In this regard, in the case where the first bonding surface 110 and the second bonding surface 120 are positionally fixed relative to each other, the distance between the first bonding surface 110 and the second bonding surface 120 is not changed when the polymer 130 linked to the first bonding surface 110 and the second bonding surface 120 is shrunk, thus making it easier to orient the polymer main chains 130A in the intersecting direction X that intersects with the first bonding surface 110 and the second bonding surface 120.

### Experimental Example 1

As shown in FIG. 8A, PPS sheets 3a made of PPS (polyphenylene sulfide resin) of 1 mm in width and 100 μm in thickness were placed on opposing end edges of the surface of a pure aluminum plate 11a of 2 mm in thickness and 22 mm on a side. Then, as shown in FIG. 8B, the space on the surface of the pure aluminum plate 11a with the PPS sheets 3a placed thereon was densely filled with the polymer material 135A composed of polymer particles (polyethylene particles, from Sumitomo Seika Chemicals Co., Ltd., “FLOWBEADS CL2080”) coated with (3-triethoxysilylpropyl) amino-1,3,5-triazine-2,4-diazido as bonding molecules. Then, as shown in FIG. 8C, a pure aluminum plate 12a similar to that mentioned above was placed on the surface of the polymer material layer composed of the polymer material 135A. Thus, a stacked body 4a was formed in which the polymer material layer composed of the polymer material 135A was disposed between the surface of the lower pure aluminum plate 11a and the upper pure aluminum plate 12a. It is to be noted that in the case of the present experimental example, the PPS sheets 3a function as spacer members, and the respective positions of the lower pure aluminum plate 11a and upper pure aluminum plater 12a are thus fixed so as not to come closer to each other.

Then, the polymer material layer was heated with the stacked body 4a sandwiched between a pair of heaters heated to 160° C. Then, after checking the polymer particles were molten, the heaters were removed, and the stacked body 4a was immersed in pure water, and then rapidly cooled. Thus, a bonded structure as a sample 1-1 was obtained.

It is to be noted that in the preparation of the sample 1-1, the heating with the heaters after disposing the polymer material layer forms covalent bonds between the polymer chains of the polymer and the bonding molecules, and forms covalent bonds between the bonding molecules and the surface of the lower pure aluminum plate. Similarly, the heating forms covalent bonds between the polymer chains of the polymer and the bonding molecules, and forms covalent bonds between the bonding molecules and the surface of the upper pure aluminum plate. In addition, the heating with the heaters increases the temperature of the polymer material layer, and the covalent bonds mentioned above are considered produced around a temperature of 120° C. or higher and lower than 145° C. at which polyethylene is melted. Furthermore, the polyethylene is melted when the temperature of the polymer material layer reaches 145° C. or higher, and the polyethylene is resolidified by the subsequent cooling, thereby causing a polyethylene shrinkage of about 38% in the present experimental example.

In the same manner as in the preparation of the bonded structure as the sample 1-1 except for the removal of the PPS sheets 3a as spacer members, a bonded structure as a sample 1-2 was obtained.

For the sample 1-1 and sample 1-2 obtained, the oriented states of the polymer main chains in the polymers of the bonding resin layers were checked with the use of Raman spectroscopy. In general, in Raman spectroscopy, the directions of molecular vibrations in the polymer can be observed through the use of a polarization filter. More specifically, the oriented states of the polymer main chains are determined. The oriented polymer main chains change the ratio of the Raman intensity of the side chain vibration of the polymer to the Raman intensity of the main chain vibration of the polymer. Thus, checking the amount of the change can determine the degree of orientation of the polymer main chains. In the case of the present experimental example, the peak of the Raman intensity appears at a wavelength of 1060 (cm⁻¹) for the skeleton vibration of a C—C bond that forms the main chain skeleton of the polymer used. In addition, the peak of the Raman intensity appears at a wavelength of 2750 (cm⁻¹) for the vibration of a C—H bond that forms the side chain of the polymer used.

FIG. 9 shows the relation (Raman spectrum) between the wavelength and the Raman intensity in the measurement for the sample 1-1 and the sample 1-2. It is to be noted that the measurement by Raman spectroscopy was made for a surface perpendicular to the thickness direction of the bonding resin layer after the removal of the upper pure aluminum plate for each sample. From FIG. 9, it is determined that the sample 1-1 has a higher Raman intensity detected for the vibration of the C—H bond than the sample 1-2 with the non-oriented polymer main chains of the polymer in the bonding resin layer. From the foregoing, it is determined that the polymer main chains of the polymer are oriented in the intersecting direction that intersects with the surface of the lower pure aluminum plate and the surface of the upper pure aluminum plate in the sample 1-1. Furthermore, the ratio 1=(Raman intensity for side chain vibration of polymer)/(Raman intensity for main chain vibration of polymer) was 11.3, which was calculated from the measurement results for the sample 1-2. In addition, the ratio 2=(Raman intensity for side chain vibration of polymer)/(Raman intensity for main chain vibration of polymer) was 12.5, which was calculated from the measurement results for the sample 1-1. Accordingly, it is determined that the orientation ratio of the polymer, defined by 100× ratio 2/ratio 1, is 3% or more in the case of the bonding resin layer in the sample 1-1.

Next, for the sample 1-1 and the sample 1-2, the thermal resistance was measured in accordance with ASTM E1530. Then, from the results obtained, the thermal conductivity was calculated. As a result, the thermal conductivity of the sample 1-1 was 2.4 W/m·K. In addition, the thermal conductivity of the sample 1-2 was 0.2 W/m·K. As described above, orienting the polymer main chains of the polymer in the intersecting direction that intersects with the surface of the lower pure aluminum plate and the surface of the upper pure aluminum plate has, in spite of the bonding with the resin used, reduced the thermal resistance in the bonding resin layer, thereby allowing the thermal conductivity to be improved.

### Experimental Example 2

Multiple samples varied in the molecular structure of the polymer and the shrinkage ratio of the polymer were prepared by variously changing the type of the polyethylene particles in the preparation of the sample 1-1 according to Experimental Example 1. Then, in the same manner as in Experimental Example 1, the thermal resistance was determined, and the thermal conductivity was calculated. The results are shown in FIG. 10. From FIG. 10, it is determined that the linear polymer is shrunk, thereby making it easier to improve the thermal conductivity. This is believed to be because the use of the linear polymer resulted in the orientation of the polymer main chains in a direction in which heat is more likely to flow, that is, in a direction that extends along the thickness direction of the bonding resin layer, between the lower pure aluminum plate and the lower pure aluminum plate.

### Experimental Example 3

As shown in FIG. 11, polyimide tapes 3b of 1 mm in width and 66 μm in thickness were placed on opposing end edges of the surface of a pure aluminum plate 11a of 1 mm in thickness and 22 mm on a side. Then, a polymer material 135B composed of a slurry (solid content of polymer particles: 40%) obtained by diluting, with a mixed solvent of water and ethanol (the mixture ratio was water:ethanol=2:1), polymer particles (polyethylene particles, from Sumitomo Seika Chemicals Co., Ltd., “FLOWBEADS CL2080”) coated with (3-triethoxysilylpropyl)amino-1,3,5-triazine-2,4-diazido as bonding molecules was applied without any space to the space on the surface of the pure aluminum plate 11a with the polyimide tapes 3b placed. Then, a heat dissipation fin 22 made of an aluminum alloy thin film was placed on the surface of the polymer material layer composed of the polymer material 135B. Thus, a stacked body 4b was formed in which the polymer material layer composed of the polymer material 135B was disposed between the surface of the lower pure aluminum plate 11a and leading projections of the upper heat dissipation fin 22. It is to be noted that in the case of the present experimental example, the polyimide tapes 3b function as spacer members, and the respective positions of the lower pure aluminum plate 11a and upper heat dissipation fin 22 are thus fixed so as not to come closer to each other.

Then, the stacked body 4b was placed with the pure aluminum plate 11a down on a heater heated to 160° C. to heat the polymer material layer.

Then, after checking the polymer particles were molten, the heaters were removed, and the stacked body 4b was immersed in pure water, and then rapidly cooled. Thus, a bonded structure as a sample 3-1 was obtained.

It is to be noted that in the preparation of the sample 3-1, the heating with the heater after disposing the polymer material layer forms covalent bonds between the polymer chains of the polymer and the bonding molecules, and forms covalent bonds between the bonding molecules and the surface of the lower pure aluminum plate. Similarly, the heating forms covalent bonds between the polymer chains of the polymer and the bonding molecules, and forms covalent bonds between the bonding molecules and the surfaces of the leading projections of the upper heat dissipation fin. In addition, the heating with the heater increases the temperature of the polymer material layer, and the covalent bonds mentioned above are considered produced around a temperature of 120° C. or higher and lower than 145° C. at which polyethylene is melted. Furthermore, the evaporation of the mixed solvent is started from the stage in which the temperature of the polymer material layer reached approximately 70° C., and when the temperature of the polymer material layer reached 145° C. or higher, the polyethylene is melted, and resolidified by the subsequent cooling. In the present experimental example, the polyethylene is thus shrunk.

For the sample 3-1 obtained, the heat flow of the bonding resin layer was measured, and the thermal conductivity was determined. Specifically, as shown in FIG. 12, a heat flow sensor 92 (from DENSO CORPORATION, “Energy Eye”) and the bonded structure 1 as the sample 3-1 were placed in this order on a heater 91 at 35.6° C. Then, as indicated by an arrow C, cold air at 21.6° C. was blown to the sample at an air speed of 3 m/s. Thus, heat from the heater 91 was, as indicated by an arrow H, released into the atmosphere through the sample. The amount of heat in this case was measured by the heat flow sensor 92 to measure the heat flow of the bonding resin layer, and the thermal conductivity was determined.

As a result, the thermal conductivity of the bonding resin layer was 4.8 W/m·K or more. In contrast, the thermal conductivity of a bonding resin layer was 0.2 W/m·K in a separately prepared comparative sample including the bonding resin layer in which polymer main chains were non-oriented (random). It is to be noted that the comparative sample was prepared from a 0.2 W/m·K heat dissipation tape and a 1.0 W/m·K heat dissipation tape.

### Experimental Example 4

Prepared were the polymer material (powder) according to Experimental Example 1 and the polymer material (slurry) according to Experimental example 3. Then, PPS sheets made of PPS (polyphenylene sulfide resin) of 1 mm in width and 100 μm in thickness were placed on opposing end edges of the surface of a pure aluminum plate of 2 mm in thickness and 22 mm on a side. Then, the space on the surface of the pure aluminum plate with the PPS sheets placed was densely filled with the polymer material (powder) according to Experimental Example 1, or the polymer material (slurry) according to Experimental example 3 was applied to the space without any space. Then, a pure aluminum plate similar to that mentioned above was placed on the surface of the polymer material layer composed of the polymer material (powder) according to Experimental Example 1 or the polymer material (slurry) according to Experimental example 3. Thus, a stacked body 4a was formed in which the polymer material layer composed of the polymer material (powder) was disposed between the surface of the lower pure aluminum plate 11a and the upper pure aluminum plate, and each stacked body was formed in which the polymer material layer composed of the polymer material (slurry) was disposed therebetween.

Then, each polymer material layer in each stacked body was heated with each stacked body sandwiched between a pair of heaters heated to 160° C. Then, after checking the polymer particles were molten, the heaters were removed, and each stacked body was immersed in pure water, and then rapidly cooled. Thus, a bonded structure as a sample 4-1 (with the polymer material (powder) used) and a bonded structure as a sample 4-2 (with the polymer material (slurry) used) were obtained.

The amount of the solvent in the polymer material used varies in the preparation of the sample 4-1 and sample 4-2. The use of such a polymer material allows the volume reduction of the polymer material to be controlled with the amount of the solvent as indicated by an arrow G in FIG. 13, thereby making it possible to change the shrinkage ratio of the polymer, and then prepare bonded structures that differ in thermal conductivity.

The present disclosure is not to be considered limited to the respective embodiments or respective experimental examples mentioned above, and can be variously modified without departing from the scope of the disclosure. In addition, the respective configurations represented in the respective embodiments and the respective experimental examples can be arbitrarily combined. More specifically, although the present disclosure is described with reference to the embodiments, it is understood that the present disclosure is not to be considered limited to the embodiments, the structures, or the like. The present disclosure encompasses even various modification examples and modifications in the equivalent scope. In addition, various combinations and forms, and furthermore, other combinations and forms including only one element or more or less besides the various combinations and forms are even considered to fall within the idea of the present disclosure.

Moreover, although an example of employing the above-mentioned bonded structure for bonding members of a heat exchanger to each other has been described in each embodiment, the bonded structure can be additionally employed for bonding, for example, a heat exchanger and piping or the like, and a heat exchanger and a component in the vicinity of the heat exchanger. Additionally, the bonded structure can be also employed for bonding an insert member such as a metal member and a resin member in the case of insert molding.

What is claimed is:

1. A bonded structure comprising:
a first bonded member having a first bonding surface;
a second bonded member having a second bonding surface; and
a bonding resin layer comprising a polymer, disposed between the first bonding surface and the second bonding surface,
wherein the polymer comprises polymer main chains oriented in an intersecting direction that intersects with the first bonding surface and the second bonding surface.

2. The bonded structure according to claim 1, wherein the intersecting direction extends along a thickness direction of the bonding resin layer.

3. The bonded structure according to claim 1, wherein the polymer comprises first polymer chains linked to the first bonding surface by a covalent bond, and second polymer chains linked to the second bonding surface by a covalent bond.

4. The bonded structure according to claim 3,
wherein bonding molecules linked to the first polymer chains by a covalent bond is linked to the first bonding surface by a covalent bond, and
bonding molecules linked to the second polymer chains by a covalent bond is linked to the second bonding surface by a covalent bond.

5. The bonded structure according to claim 1, wherein the polymer is a linear polymer.

6. The bonded structure according to claim 1, wherein the first bonding surface and the second bonding surface have positions fixed relative to each other.

7. The bonded structure according to claim 1, wherein the bonding resin layer has a thermal conductivity of 1 W/m·K or more.

8. The bonded structure according to claim 1, wherein in the bonding resin layer, the polymer has an orientation ratio of 3% or more, the orientation ratio defined by 100×ratio 2/ratio 1,
wherein
the ratio 1: an absolute value of a ratio (Raman intensity for side chain vibration of the polymer)/(Raman intensity for main chain vibration of the polymer), determined for a plane perpendicular to the thickness direction of the bonding resin layer in a non-oriented sample in which the polymer main chain constituting the polymer is not oriented; and
the ratio 2: an absolute value of a ratio (Raman intensity for side chain vibration of the polymer)/(Raman intensity for main chain vibration of the polymer), determined for a plane perpendicular to the thickness direction of the bonding resin layer in an oriented sample in which the polymer main chain constituting the polymer is oriented.

9. A heat exchanger comprising the bonded structure according to claim 1,
wherein the first bonded member serves as a tubular member, and the second bonded member serves as a heat dissipation fin.

10. A method for producing the bonded structure according to claim 1, the method comprising:
disposing a polymer material comprising the polymer between the first bonding surface of the first bonded member and the second bonding surface of the second bonded member; and
heating the polymer material disposed, and then cooling the polymer material,
wherein between disposing and cooling the polymer material, polymer chains of the polymer are linked by covalent bonds to the first bonding surface and the second bonding surface, and the polymer is then shrunk to orient the polymer main chains in the intersecting direction that intersects with the first bonding surface and the second bonding surface.

11. The method for producing the bonded structure according to claim 10, wherein the first bonding surface and the second bonding surface have positions fixed relative to each other.
